(19) United States
(12) Patent Application Publication
(10) Pub. No.: US 2026/0316232 A1
(43) Pub. Date: Oct. 15, 2026

(54) POWER TOOL WITH IMPULSE ASSEMBLY

(71) Applicant: MILWAUKEE ELECTRIC TOOL CORPORATION, Brookfield, WI (US)

(72) Inventors: Wei Chao Xu, Guigang City (CN); Xiao Long Le, Ji An City (CN); Wen Wei Huang, Dongguan City (CN)

(21) Appl. No.: 19/467,336

(22) Filed: Feb. 2, 2026

Related U.S. Application Data
(60) Provisional application No. 63/753,244, filed on Feb. 3, 2025.

(51) Int. Cl. B25B 21/02; B25F 5/00; B25F 5/02

(52) U.S. Cl. CPC B25B 21/02; B25F 5/001; B25F 5/02

(57) ABSTRACT

A power tool for delivering torque impulses to a tool bit includes a motor and an impulse assembly driven by the motor. The impulse assembly has an anvil assembly and a hammer assembly that imparts a torque impulse to the anvil assembly. The anvil assembly includes an anvil with a passageway between a hammer chamber and an anvil chamber, both containing hydraulic fluid. A blade is coupled to the anvil and impacted by the hammer assembly, with a biasing member and a piston positioned to control the blade's movement. This configuration enables the power tool to efficiently deliver torque impulses to the tool bit.

### CROSS-REFERENCE

This application claims priority to U.S. Provisional Patent Application No. 63/753,244, filed February 3, 2025, the entire content of which is incorporated herein by reference.

### FIELD

The present disclosure relates to power tools, and more particularly to gas spring-powered fastener drivers.

### BACKGROUND

Impulse power tools can deliver torque impulses to a workpiece at high speeds by accumulating energy in a rotating mass and transmitting the energy to an output shaft. The output shaft may be capable of holding a tool bit or engaging a socket. Impulse tools typically utilize percussive transfers of high momentum, which is transmitted through the output shaft using a variety of means, such as electric or electromagnetic mechanisms, oil-pulse mechanisms, mechanical-pulse mechanisms, or any suitable combination thereof.

### SUMMARY

In some aspects, the techniques described herein relate to a power tool configured to deliver torque impulses to a tool bit, the power tool including: a housing; a motor positioned within the housing; and an impulse assembly supported within the housing and configured to be driven by the motor, the impulse assembly including an anvil assembly and a hammer assembly configured to impart a torque impulse to the anvil assembly, the impulse assembly defining a hammer chamber and an anvil chamber each containing a hydraulic fluid; wherein the anvil assembly includes: an anvil defining a passageway communicating between the hammer chamber and the anvil chamber, a blade coupled to the anvil and configured to be impacted by the hammer assembly, a biasing member configured to bias the blade toward the hammer assembly, and a piston positioned between the biasing member and the blade.

In some aspects, the techniques described herein relate to a power tool, wherein the anvil defines a transverse bore and the piston is positioned within the transverse bore.

In some aspects, the techniques described herein relate to a power tool, wherein the biasing member includes a spring positioned within the transverse bore.

In some aspects, the techniques described herein relate to a power tool, wherein the piston is configured to reciprocate within the transverse bore in response to movement of the blade.

In some aspects, the techniques described herein relate to a power tool, wherein the piston is configured to limit fluid flow through the transverse bore.

In some aspects, the techniques described herein relate to a power tool, wherein the piston includes a peripheral outer surface configured to seal against an inner surface of the transverse bore.

In some aspects, the techniques described herein relate to a power tool, wherein the piston includes an open end defining a cavity that receives a portion of the biasing member.

In some aspects, the techniques described herein relate to a power tool, wherein the piston is closed at opposite ends and contacts both the biasing member and the blade.

In some aspects, the techniques described herein relate to a power tool, wherein the passageway includes a restricted flow passageway having an adjustable cross-sectional area.

In some aspects, the techniques described herein relate to a power tool configured to deliver torque impulses to a tool bit, the power tool including: a housing; a motor positioned within the housing; and an impulse assembly supported within the housing and configured to be driven by the motor, the impulse assembly including an anvil assembly and a hammer assembly configured to impart a torque impulse to the anvil assembly; wherein the anvil assembly includes: an anvil defining a transverse bore, a blade coupled to the anvil and configured to be impacted by the hammer assembly, a biasing member configured to bias the blade toward the hammer assembly, and a piston positioned within the transverse bore between the biasing member and the blade.

In some aspects, the techniques described herein relate to a power tool, wherein the piston includes a peripheral wall defining an open end and an end wall defining a closed end.

In some aspects, the techniques described herein relate to a power tool, wherein the peripheral wall further defines a cavity that receives a portion of the biasing member.

In some aspects, the techniques described herein relate to a power tool, wherein the anvil further defines an axial bore intersecting the transverse bore.

In some aspects, the techniques described herein relate to a power tool, wherein the biasing member includes a spring positioned within the transverse bore.

In some aspects, the techniques described herein relate to a power tool, wherein the piston includes a protrusion configured to engage the spring and inhibit buckling of the spring.

In some aspects, the techniques described herein relate to a power tool, wherein the impulse assembly further includes a camshaft configured to selectively open and close a fluid passageway between a hammer chamber and an anvil chamber.

In some aspects, the techniques described herein relate to a power tool, wherein the camshaft rotates with the hammer assembly.

In some aspects, the techniques described herein relate to an impulse assembly for a power tool, the impulse assembly including: an anvil assembly including an anvil defining a transverse bore; a blade movably coupled to the anvil and configured to be impacted by a hammer assembly; a biasing member positioned in the transverse bore and configured to bias the blade toward an extended position; and a piston positioned in the transverse bore between the biasing member and the blade; wherein the piston is configured to reciprocate within the transverse bore with movement of the blade and to restrict fluid flow through the transverse bore.

In some aspects, the techniques described herein relate to an impulse assembly, wherein the piston includes a peripheral wall having an outer surface that sealingly engages an inner surface of the transverse bore to inhibit hydraulic fluid flow through the transverse bore.

In some aspects, the techniques described herein relate to an impulse assembly, wherein the piston is cup-shaped and defines an open end forming a cavity that receives an end portion of the biasing member.

Other aspects of the disclosure will become apparent by consideration of the detailed description and accompanying drawings.

### BRIEF DESCRIPTION OF THE DRAWINGS

FIG. 1 is a perspective view of a power tool according to an embodiment of the present disclosure.

FIG. 2 is a side view showing the power tool of FIG. 1 with portions removed.

FIG. 3 is a cross-sectional view of the power tool of FIG. 1, taken along line 3—3 of FIG. 1.

FIG. 4 is a perspective view of a drive assembly of the power tool of FIG. 1.

FIG. 5 is a partially exploded perspective view of the drive assembly of FIG. 4.

FIGS. 6A and 6B are perspective views of an impulse assembly of the power tool of FIG. 1.

FIG. 7 is a partially exploded perspective view of the impulse assembly of FIG. 6A.

FIG. 8 is a cross-sectional view of the impulse assembly of FIG. 6A, taken along line 8—8 of FIG. 6A.

FIG. 9 is a cross-sectional view of the impulse assembly of FIG. 6A, taken along line 9—9 of FIG. 6A.

FIG. 10A is a cross-sectional view of the impulse assembly of FIG. 6A, taken along line 10A—10A of FIG. 6A and illustrating a hammer assembly oriented at a starting position relative to the anvil assembly.

FIG. 10B is a detailed cross-sectional view showing portions of the impulse assembly of FIG. 6A, taken along line 9—9 of FIG. 6A and showing the hammer assembly of FIG. 10A oriented at the starting position.

FIG. 11A is a cross-sectional view of the impulse assembly of FIG. 6A, taken along line 10A—10A of FIG. 6A and illustrating the hammer assembly of FIG. 10A oriented at an initial impact position relative to the anvil assembly.

FIG. 11B is a detailed cross-sectional view showing portions of the impulse assembly of FIG. 6A, taken along line 9—9 of FIG. 6A and showing the hammer assembly of FIG. 10A oriented at the initial impact position.

FIG. 12A is a cross-sectional view of the impulse assembly of FIG. 6A, taken along line 10A—10A of FIG. 6A and illustrating the hammer assembly of FIG. 10A oriented an intermediate impact position relative to the anvil assembly.

FIG. 12B is a detailed cross-sectional view showing portions of the impulse assembly of FIG. 6A, taken along line 9—9 of FIG. 6A and showing the hammer assembly of FIG. 10A oriented at the intermediate impact position.

FIG. 13 is a cross-sectional view of an impulse assembly of the power tool of FIG. 1 according to another embodiment.

FIG. 14 is a detailed cross-sectional view showing portions of the impulse assembly of FIG. 13.

FIG. 15A is a cross-sectional view of a piston of the impulse assembly of FIG. 13 according to another embodiment.

FIG. 15B is a cross-sectional view of a piston of the impulse assembly of FIG. 13 according to another embodiment.

Before any embodiments of the disclosure are explained in detail, it is to be understood that the disclosure is not limited in its application to the details of construction and the arrangement of components set forth in the following description or illustrated in the following drawings. The disclosure is capable of other embodiments and of being practiced or of being carried out in various ways.

### DETAILED DESCRIPTION

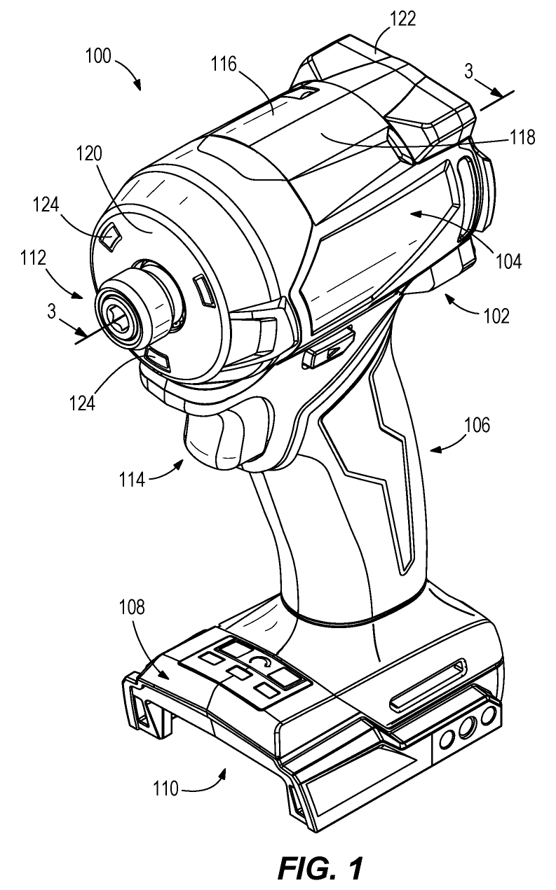

FIG. 1 illustrates a power tool embodied as an impulse driver 100. The impulse driver 100 includes a housing 102 having a motor housing portion 104, a handle portion 106, and a foot portion 108. The foot portion 108 includes a battery receptacle 110 that selectively and removably couples to a battery pack (not shown) to power the impulse driver 100. The impulse driver 100 also includes tool holder 112 which removably receives an output tool (e.g., a driver bit; not shown). The impulse driver 100 further includes a trigger 114 that, when actuated, causes the tool holder 112 to rotate (e.g., to perform a fastening operation).

In the embodiment shown in FIG. 1, the housing 102 includes a first clamshell half 116, a second clamshell half 118, a front cover 120, and a rear cover 122. The front cover 120 supports a plurality of light fixtures 124 (e.g., LED light fixtures) which are operable to light a workspace upon actuation of the trigger 114.

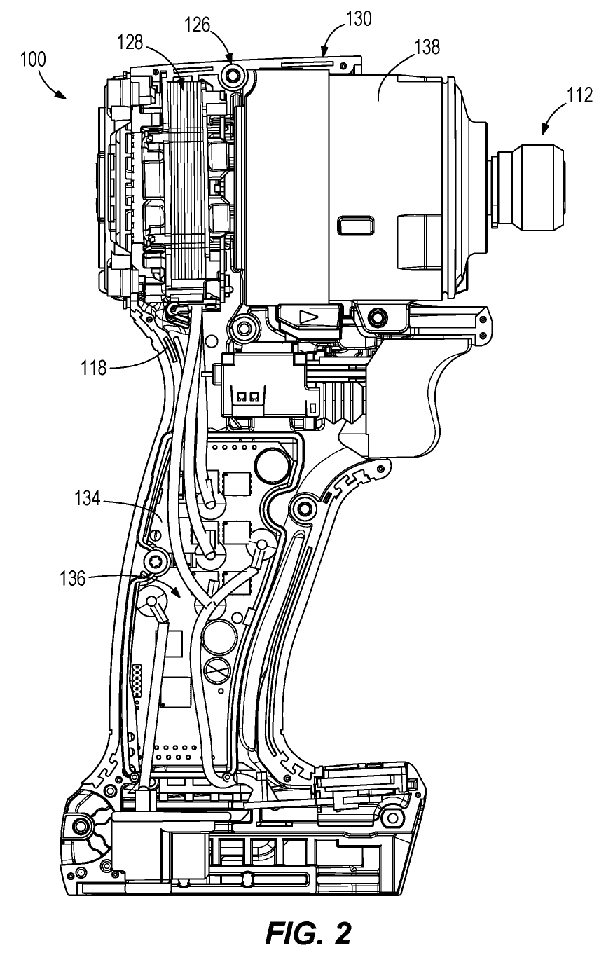

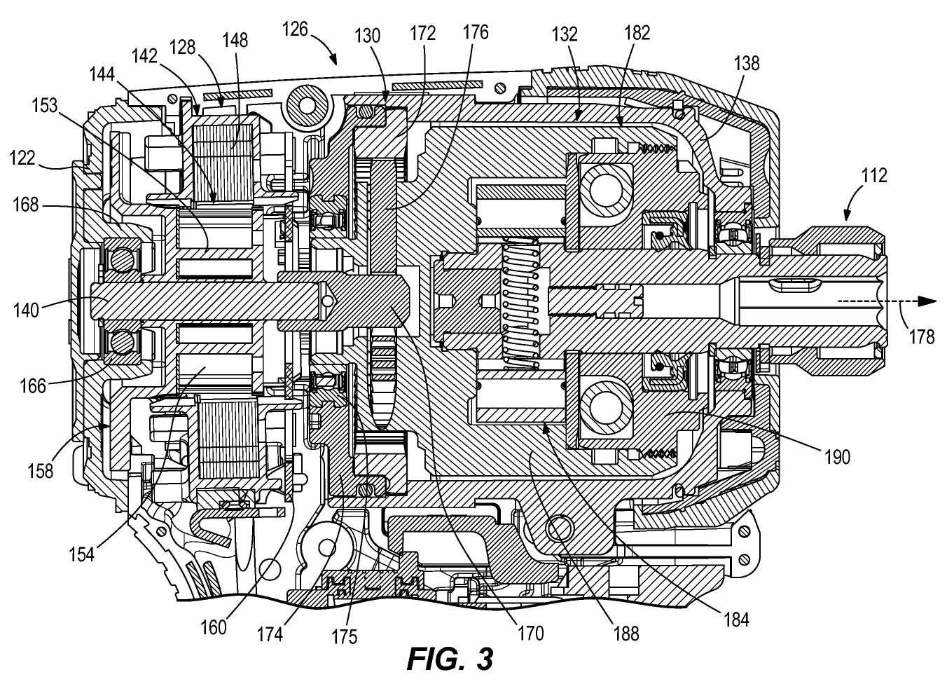

FIG. 2 illustrates the impulse driver 100 with the first clamshell half 116, the front cover 120, and the rear cover 122 removed. The impulse driver 100 includes a drive assembly 126 operable to impart torque to the tool holder 112. The drive assembly 126 includes an electric motor 128, a transmission 130, and an impulse assembly 132 (FIG. 3). The impulse driver 100 also includes a printed circuit board assembly 134 (PCBA 134) which supports a controller 136. The controller 136 is operable to control multiple aspects of the impulse driver 100, such as operation of the electric motor 128 and the plurality of light fixtures 124. For example, the controller 136 is operable to deliver electric current to the electric motor 128 to cause the electric motor 128 to start, accelerate, decelerate, or stop. The impulse driver 100 also includes an annular case 138 positioned adjacent the front cover 120 and between the clamshell halves 116, 118. The annular case 138 supports the transmission 130 and at least partially supports the electric motor 128. The annular case 138 also rotatably supports the impulse assembly 132.

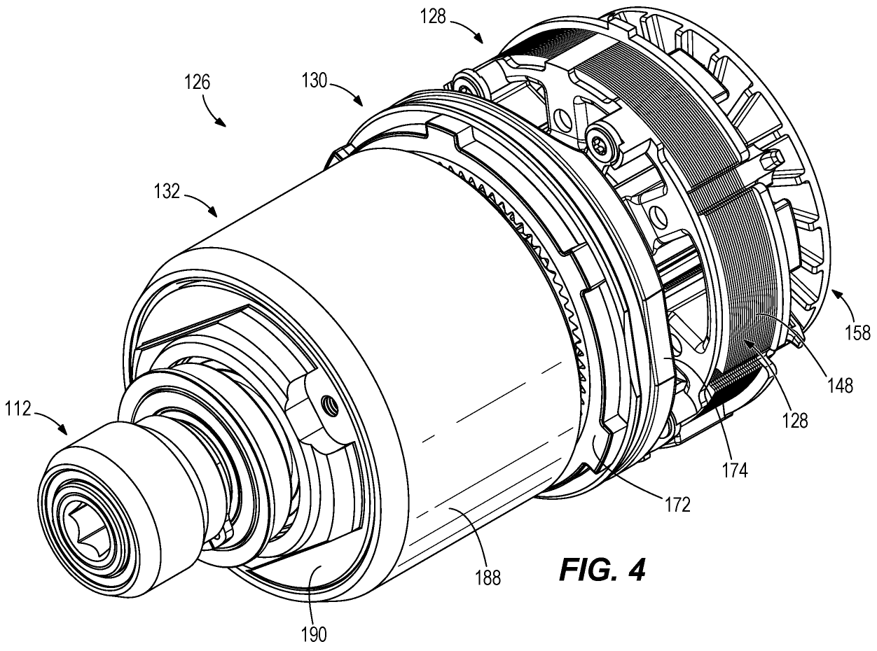

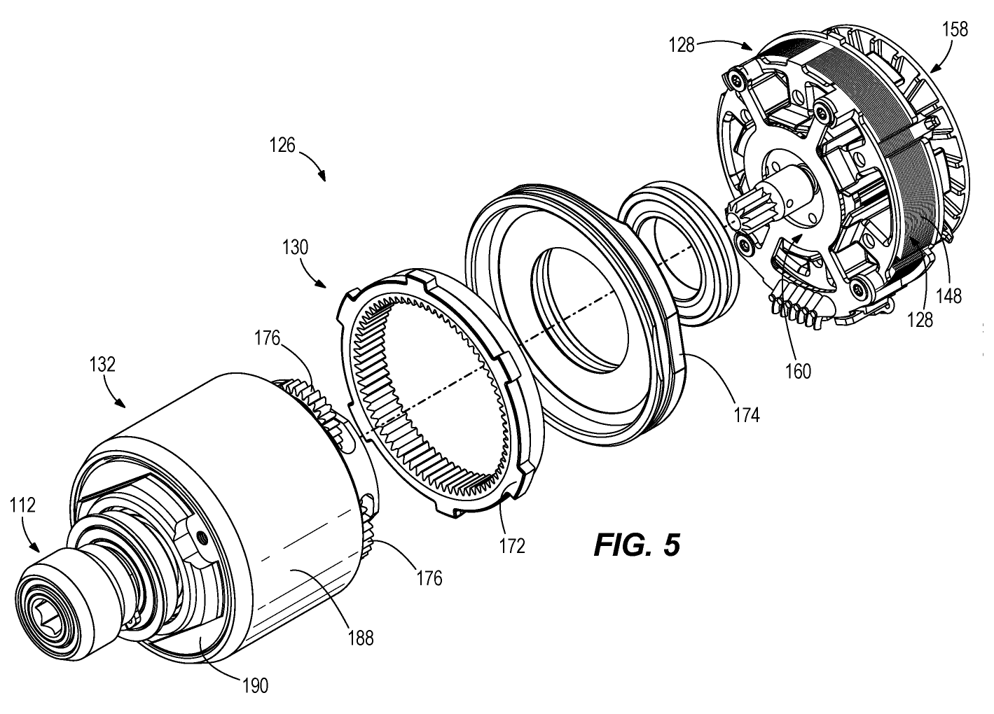

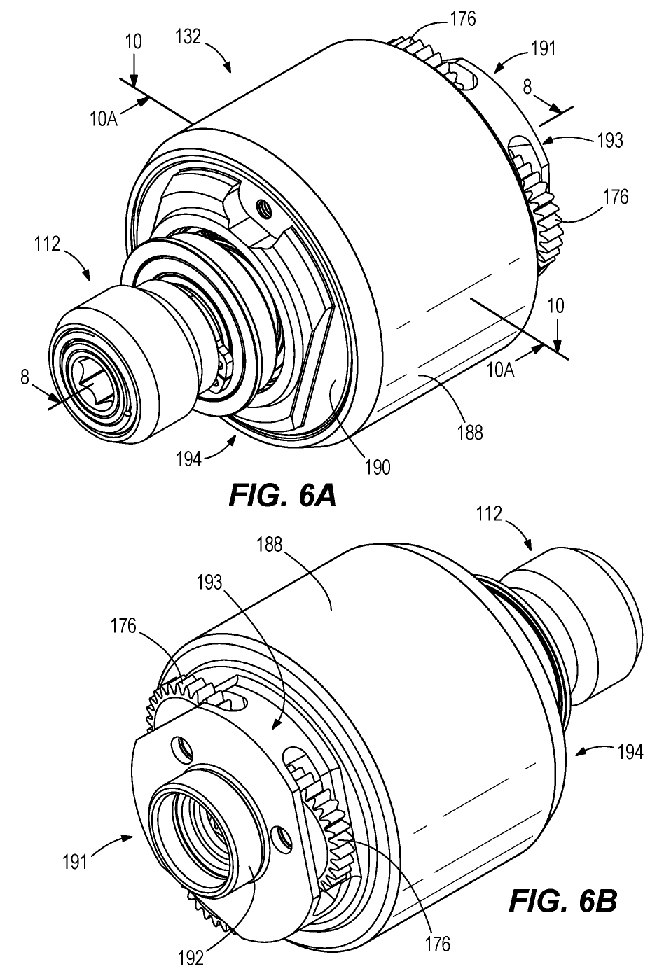

With reference to FIGS. 3-6B, the electric motor 128 is a brushless, direct-current electric motor 128 having a motor shaft 140, a stator 142, and a rotor 144 affixed to the motor shaft 140 for co-rotation therewith. The stator 142 surrounds the rotor 144. The stator 142 includes a stator core 148 supported by the housing 102 and a plurality of coils (not shown) supported on the stator core 148. The rotor 144 includes a rotor body 153 supporting a plurality of permanent magnets 154. The rotor body 153 is coupled to a fan 158 which generates a cooling airflow within the housing 102. The electric motor 128 further includes a sensor board 160 which is operable to detect a rotational position of the rotor 144 and communicate a position signal to the controller 136 (FIG. 2).

With continued reference to FIGS. 3-5, the electric motor 128 includes a motor bearing 166 positioned at a rear distal end of the motor shaft 140. The motor bearing 166 is supported about its outer race by a rear bearing support 168 which is defined by the rear cover 122. The electric motor 128 further includes an output gear 170 (e.g., a pinion), which engages the transmission 130.

The transmission 130 includes a ring gear 172 and planetary gears 176 which are supported by the impulse assembly 132. The ring gear 172 is fixedly secured to the case 138 via, e.g., press fit. The ring gear 172 is also fixedly secured to a central bearing mount 174. The central bearing mount 174 supports a central bearing 175, which rotatably supports the impulse assembly 132 for rotation about an output axis 178. The planetary gears 176 mesh with the output gear 170 and with the ring gear 172. The transmission 130 effects a rotational speed reduction from the motor shaft 140 to the impulse assembly 132 and a corresponding torque increase therebetween.

With continued reference to FIGS. 3-6B, the impulse assembly 132 includes a hammer assembly 182 and an anvil assembly 184. The hammer assembly 182 is rotatably supported within the case 138 about the anvil assembly 184 and by the central bearing 175. In the illustrated embodiment, the impulse assembly 132 is an oil impulse assembly which utilizes an incompressible fluid, such as hydraulic fluid, such as oil or the like, to effect and modulate torque impulses delivered from the hammer assembly 182 to the anvil assembly 184, as will be explained herein.

When the electric motor 128 is activated, torque is transmitted from the motor shaft 140 to the hammer assembly 182, causing the hammer assembly 182 to rotate about the output axis 178 relative to the case 138. The hammer assembly 182 includes a hammer 188 and an end cap 190 secured to the hammer 188. A rear end 191 of the hammer 188 defines an annular tail 192 which is supported by an inner race of the central bearing 175. The rear end 191 also defines planetary carrier 193 which supports the planetary gears 176. A front end 194 of the hammer 188, which is located opposite from the rear end 191 along the output axis 178, is secured to the end cap 190. Specifically, the hammer 188 is drum-shaped and includes an annular side wall 196 and a closed rear wall 198 which is located toward the rear end 191. The side wall 196 defines an opening 200 at the front end 194 and is internally threaded adjacent the opening 200. The end cap 190 is ring-shaped and is externally threaded so that it threadably tightens into the hammer 188 through the opening 200.

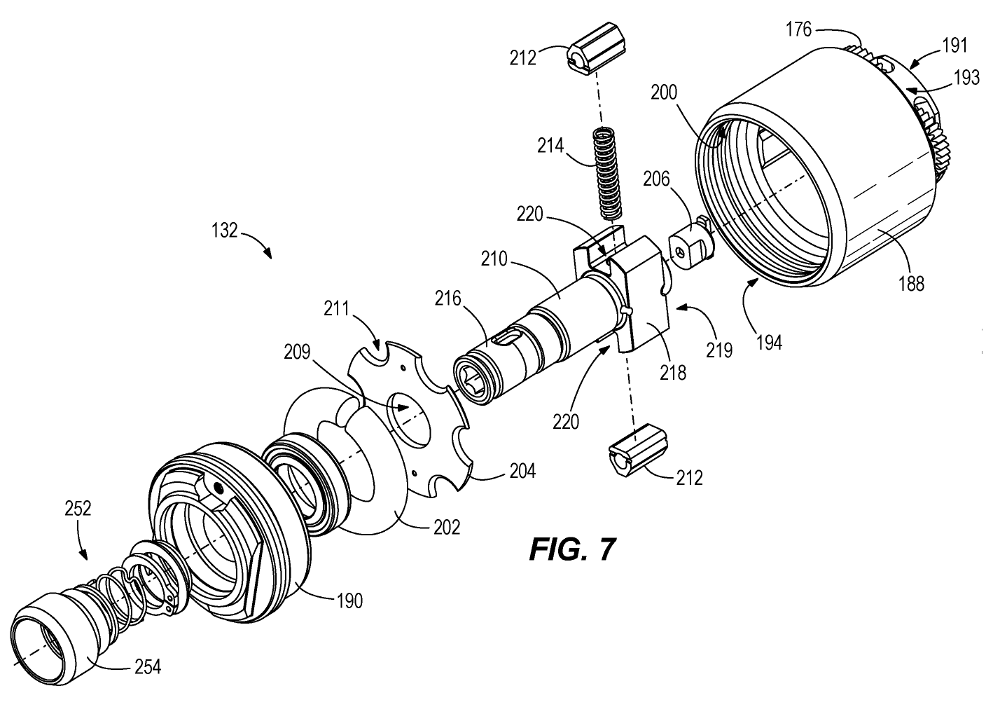

With reference to FIGS. 7-9, the hammer assembly 182 also includes a bladder 202, a friction plate 204, and a camshaft 206. The bladder 202 is annular or ring-shaped and formed from a flexible material that encloses an internal space which is filled with a compressible fluid. The end cap 190 defines an annular recess 207 which houses the bladder 202. The friction plate 204 is also annular and disk-shaped and defines an internal aperture 209 at its inner perimeter and a plurality of notches 211 at its outer perimeter. The friction plate 204 is captured between the end cap 190 and the hammer 188 and partially covers the annular recess 207 and the bladder 202. The notches 211 communicate the annular recess 207 with an interior of the hammer 188. As such, changes in a pressure of the hydraulic fluid during operation of the impulse assembly 132 are communicated to the bladder 202, which expands or contracts in response to the pressure changes to thereby modulate the pressure.

The anvil assembly 184 includes an anvil 210, a pair of blades 212, and a spring 214. The anvil 210 is elongated and includes an output shaft 216 and a block 218 integrally defined at a rear end 219 of the output shaft 216. The block 218 defines a pair of slots 220 located on opposite lateral sides of the block 218. The anvil 210 also defines a transverse bore 222 that extends internally communicates between both slots 220. The blades 212 are received into the longitudinal slots 220. The spring 214 resides in the transverse bore 222 and engages both blades 212 at its respective ends. The spring 214 biases the blades 212 radially outward, i.e., out of the slots 220 in the radial direction.

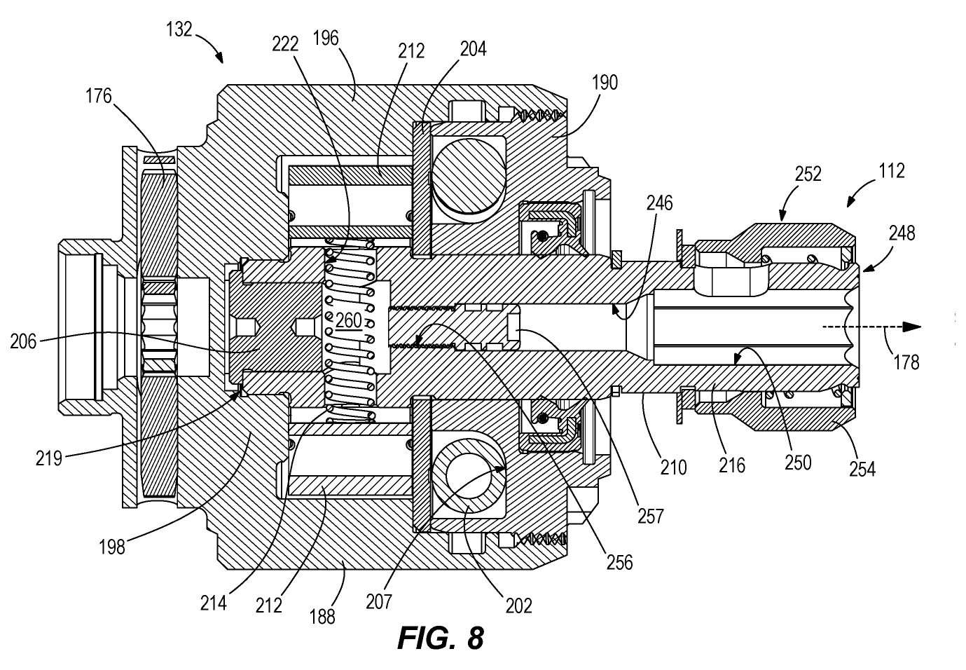

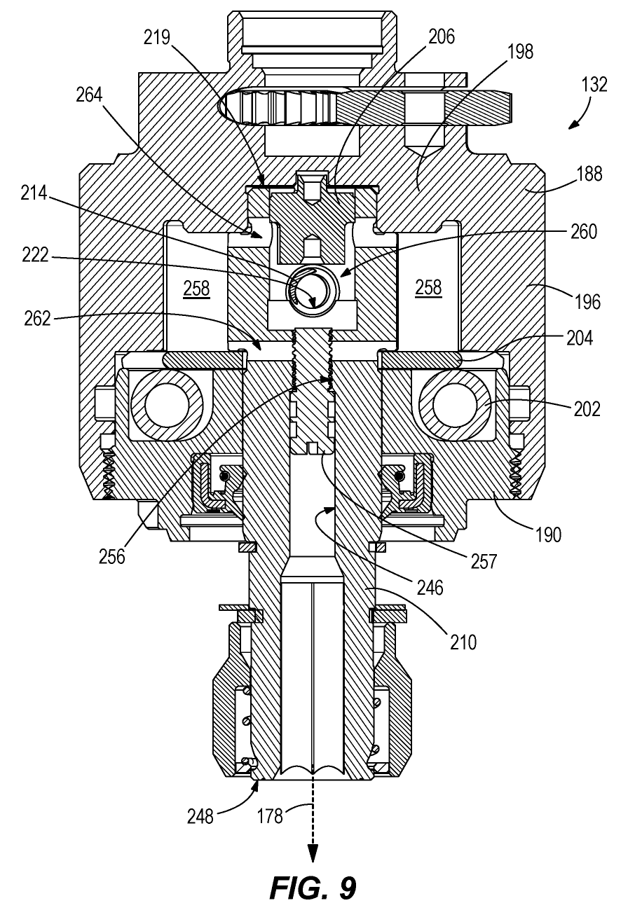

With reference to FIGS. 8 and 9, the anvil 210 defines an axial through bore 246 which extends from the rear end 219 to an output end 248, i.e., a front end thereof. The axial through bore 246 intersects the transverse bore 222. The output end 248 includes a hexagonal region 250 of the axial through bore 246, which receives a corresponding hexagonally-shaped portion of the driver bit (not shown). The tool holder 112 includes the output shaft 216, with the hexagonal region 250, and a bit retainer 252. The bit retainer 252 includes a sleeve 254 which is biased toward a lock position at which the driver bit is held or retained within the hexagonal region 250. The sleeve 254 is slidable and can be moved to a release position at which the driver bit may be removed from the hexagonal region 250.

The axial through bore 246 receives a portion of the camshaft 206 at the rear end 219 of the anvil 210. The anvil 210 also defines an internally threaded surface 256 located between the hexagonal region 250 and the transverse bore 222. The anvil assembly 184 further includes a set screw 257 which tightens into the internally threaded surface 256.

With continued reference to FIGS. 8 and 9, the impulse assembly 132 defines a hammer chamber 258 between the hammer 188, the anvil assembly 184, and the end cap 190. The hammer chamber 258 is filled with the hydraulic fluid. The impulse assembly 132 also defines an anvil chamber 260. The anvil chamber 260 is defined within the axial through bore 246 between the camshaft 206 and the set screw 257, within the transverse bore 222 and between the slots 220, the blades 212, the closed rear wall 198, and the friction plate 204. The anvil chamber 260 is also filled with the hydraulic fluid.

With reference to FIG. 9, the anvil 210 also defines a first passageway 262, or a restricted flow passageway, which communicates between the hammer chamber 258 and the anvil chamber 260. The hydraulic fluid can flow between the hammer chamber 258 and the anvil chamber 260 via the first passageway 262. The first passageway 262 also communicates with the axial through bore 246 and is located adjacent the internally threaded surface 256. As shown in FIG. 9, the set screw 257 can partially protrude into the first passageway 262 to thereby constrict or reduce a cross-sectional area of the first passageway 262. The set screw 257 can be adjusted (by rotating clockwise or counterclockwise) to increase or decrease a distance by which a tip of the set screw 257 protrudes into the first passageway 262. The set screw 257 can therefore variably adjust the area of the first passageway 262.

With continued reference to FIG. 9, the anvil 210 also defines a second passageway 264, or a fill passageway, which communicates between the hammer chamber 258 and the anvil chamber 260. The hydraulic fluid can flow between the hammer chamber 258 and the anvil chamber 260 via the second passageway 264. The second passageway 264 also communicates with the axial through bore 246 and is selectively opened or closed by the camshaft 206, as will be discussed further herein. The first passageway 262 is narrower than the second passageway 264, and thus the flow of the hydraulic fluid is more restricted through the first passageway 262 than the second passageway 264.

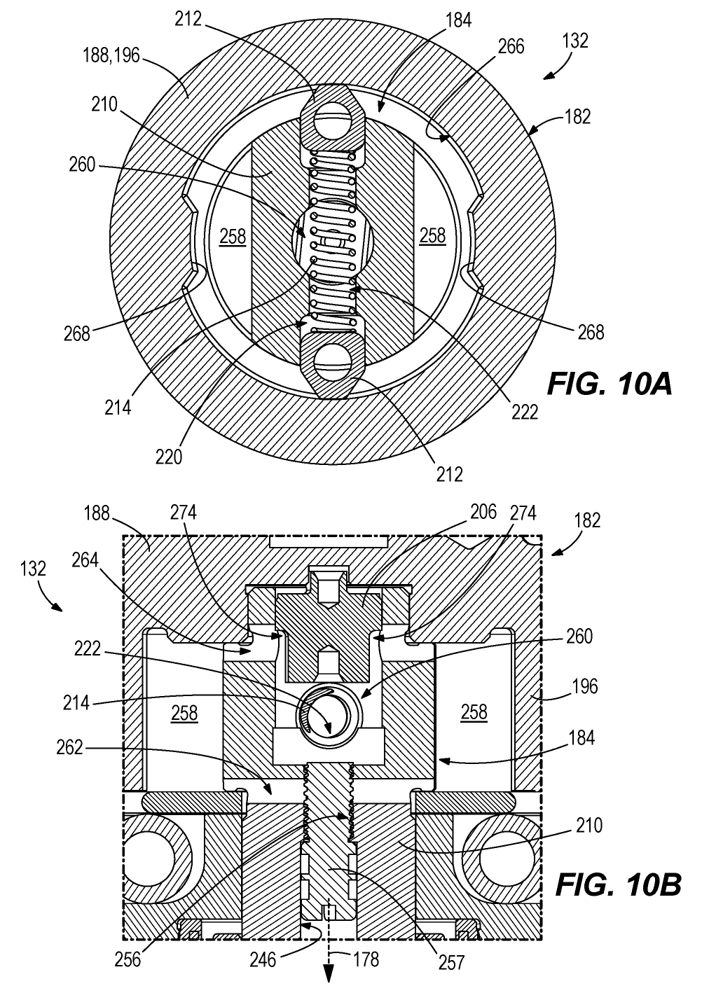

With reference to FIG. 10A, the annular side wall 196 of the hammer 188 includes an inner surface 266 and a pair of lugs 268 protruding radially inward from the inner surface 266 at opposite sides thereof. The blades 212 are arranged in facing relationship with the inner surface 266. During operation of the impulse driver 100 the hammer 188 rotates relative to the anvil assembly 184 such that the lugs 268 make repeated impacts against blades 212, as will be discussed herein.

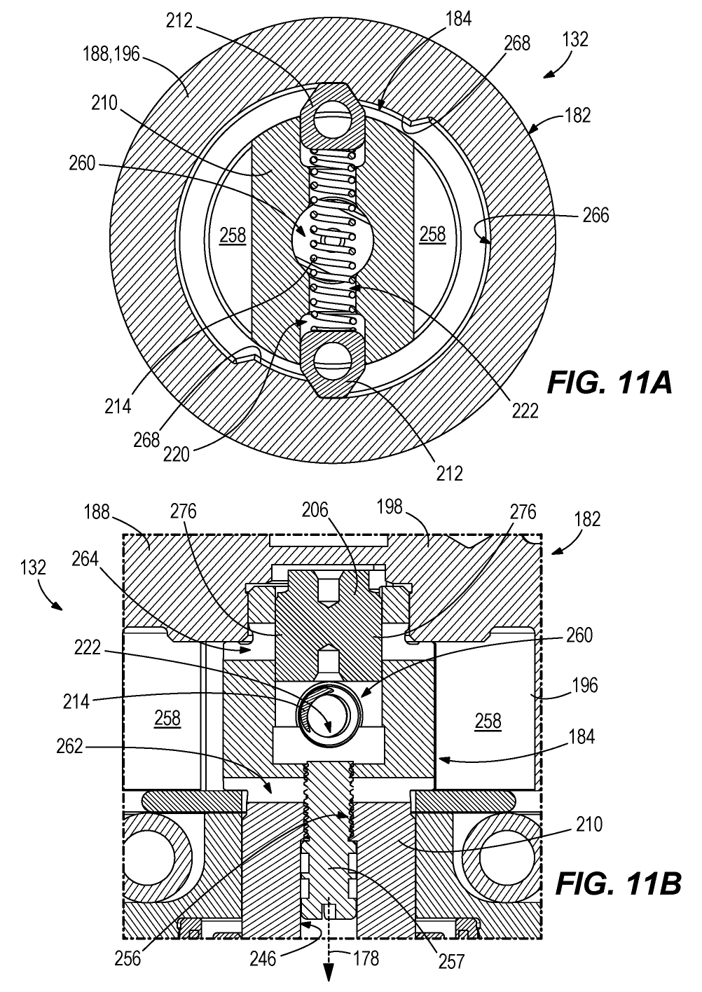

With reference to FIGS. 10B and 11B, the camshaft 206 is coupled to the hammer 188 and rotates together therewith. The camshaft 206 defines a pair of recesses or flats 274 located on opposite sides thereof. The camshaft 206 also includes a pair of lobes 276 formed between the pair of flats 274, such that the lobes 276 and the flats 274 alternate about a circumference of the camshaft 206. The camshaft 206 is received into the axial through bore 246 with the lobes 276 and the flats 274 located adjacent the second passageway 264. As the camshaft 206 rotates relative to the anvil 210, the flats 274 and the lobes 276 alternatingly close and open the second passageway 264 to permit or prevent the hydraulic fluid to flow through the second passageway 264.

Operation of the impulse driver 100 will now be described with reference to FIGS. 10A-12B. FIGS. 10A and 10B illustrate the hammer assembly 182 oriented at a starting position relative to the anvil assembly 184. When the electric motor 128 is activated, the motor shaft 140 rotates, which causes the hammer assembly 182 to rotate as torque from the motor shaft 140 is transmitted to the hammer assembly 182 via the transmission 130. In the starting position, the camshaft 206 is oriented with the flats 274 positioned adjacent the second passageway 264 such that the second passageway 264 is open. The hydraulic fluid is able to flow through the second passageway 264 between the hammer chamber 258 and the anvil chamber 260 in this orientation.

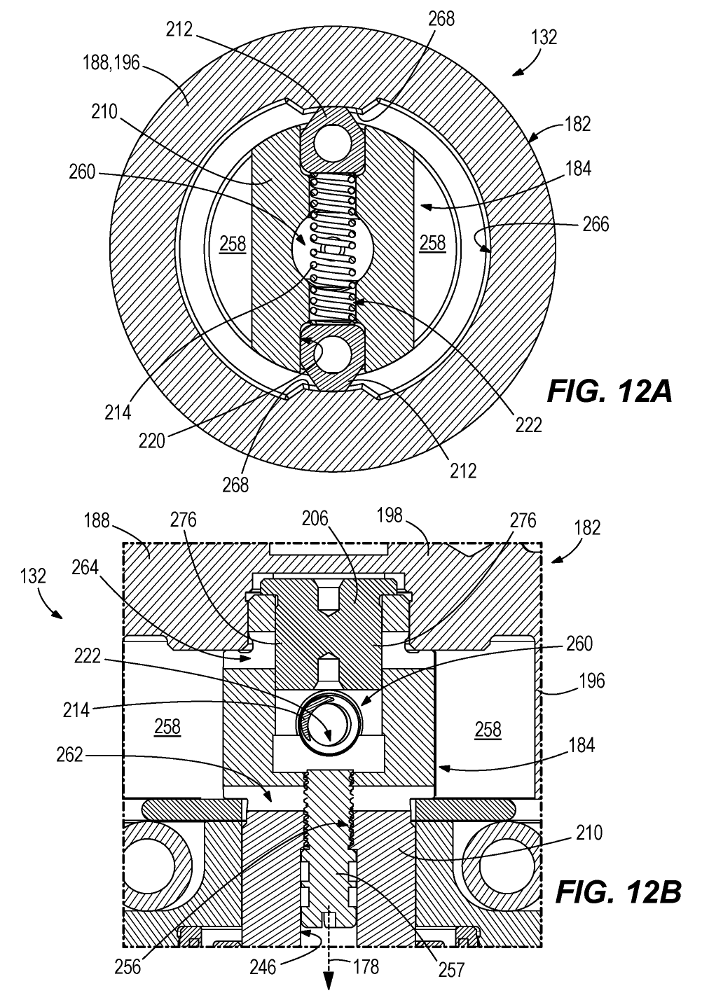

With reference to FIGS. 11A and 11B, as the hammer assembly 182 rotates relative to the anvil assembly 184 (counterclockwise from FIG. 11A to FIG. 12A), the lugs 268 approach and impact the blades 212. The impact between the lugs 268 and the blades 212 communicates torque from the hammer assembly 182 to the anvil assembly 184. The anvil assembly 184 is coupled to the output tool (e.g., the driver bit) via the tool holder 112 and transmits the torque to a working member (e.g., a fastener). As the fastener is tightened into a workpiece, it resists tightening and exerts a reactionary torque against the anvil assembly 184, causing the anvil assembly 184 to resist or cease co-rotation with the hammer assembly 182.

In the orientation shown in FIGS. 11A and 11B, the camshaft 206 is oriented with the lobes 276 positioned adjacent the second passageway 264 such that the second passageway 264 is closed by the lobes 276. The hydraulic fluid is not able to flow through the second passageway 264 between the hammer chamber 258 and the anvil chamber 260 in this orientation. However, the hydraulic fluid may still flow between the hammer chamber 258 and the anvil chamber 260 via the first passageway 262.

With reference to FIGS. 12A and 12B, when a sufficient reactionary torque is exerted against the anvil 210, the lugs 268 ramp up and slip over the blades 212, thereby pushing the blades 212 radially into the slots 220 against the bias of the spring 214. As the blades 212 retract into the slots 220, volume of the anvil chamber 260 is reduced, which causes a corresponding increase of the pressure of the hydraulic fluid within the anvil chamber 260. The second passageway 264 remains closed by the camshaft 206 in this position, such that the hydraulic fluid may only escape the anvil chamber 260 by flowing to the hammer chamber 258 via the first passageway 262. The smaller area of the first passageway 262 limits a flow rate of the hydraulic fluid therethrough. Thus, the blades 212 may only retract into the slots 220 at a rate governed by the flow rate of the hydraulic fluid through the first passageway 262. The hydraulic fluid may therefore slow and damp inward movement of the blades 212 and thereby increase the duration over which the lugs 268 engage the blades 212. The hydraulic fluid may also reduce noise emissions and inhibit wear on the components of the hammer assembly 182 and anvil assembly 184 throughout impact.

Eventually, the hammer assembly 182 rotates relative to the anvil assembly 184 past the position shown in FIGS. 12A and 12B and returns to a position like that shown in FIGS. 10A and 10B. The camshaft 206 again becomes oriented with the flats 274 positioned adjacent the second passageway 264 such that the second passageway 264 is open. The hydraulic fluid is able to flow through the second passageway 264 between the hammer chamber 258 and the anvil chamber 260 in this orientation. The spring 214 biases the blades 212 back out from the slots 220, which causes the volume of the anvil chamber 260 to increase. The hydraulic fluid may flow from the hammer chamber 258 back into the anvil chamber 260 via both passageways 262, 264.

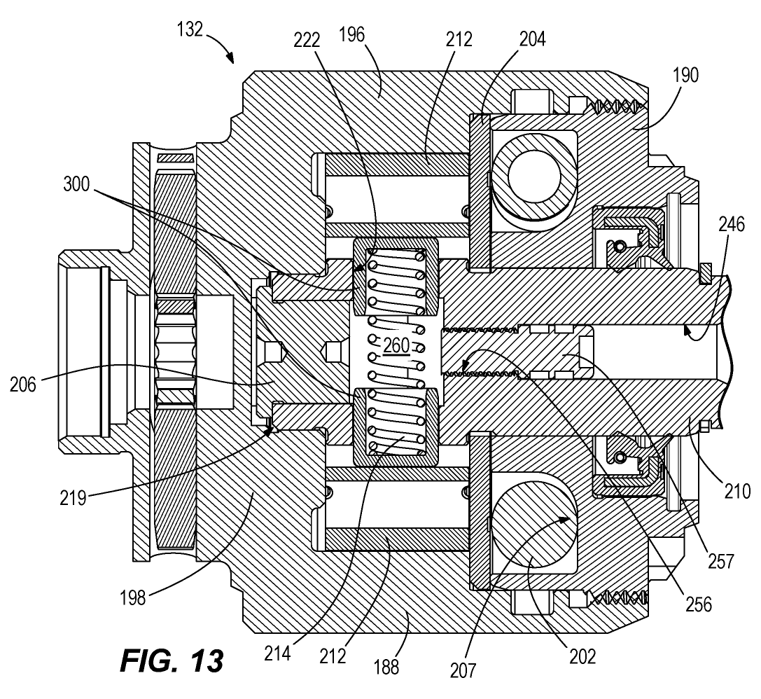

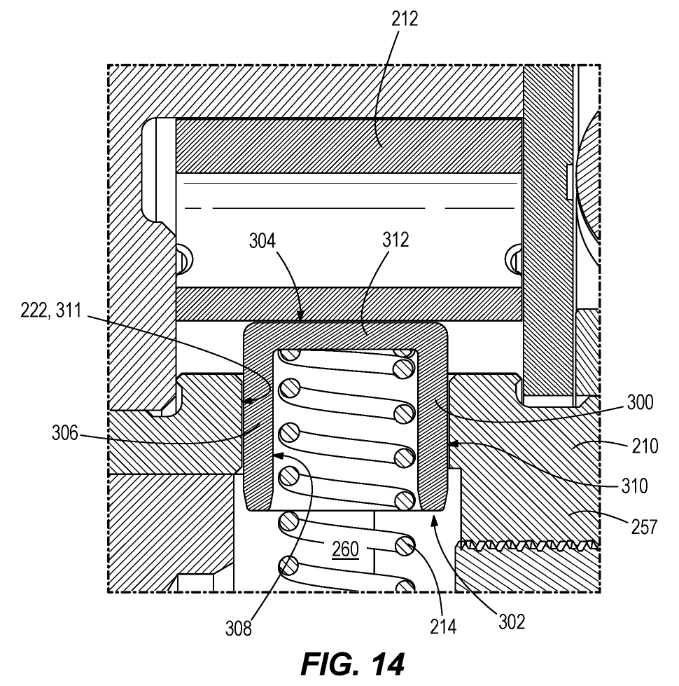

With reference to FIGS. 13 and 14, the anvil assembly 184 further includes two seal members, or pistons 300, positioned within the transverse bore 222. The pistons 300 limit the flow of hydraulic fluid through the transverse bore 222 between the hammer chamber 258 (FIG. 9) and the anvil chamber 260. The pistons 300 are located between the respective ends of the spring 214 and the blades 212. The pistons 300 can contact both the blades 212 and the ends of the spring 214 to communicate the biasing force of the spring 214 to each respective blade 212. The pistons 300 can also contact and seal against an inner surface of the transverse bore 222 to prevent the flow of hydraulic fluid therethrough.

In the illustrated embodiment, each piston 300 is cup-shaped and includes an open end 302 and a closed end 304. Each piston 300 includes a peripheral wall 306 that defines the open end 302 and a cavity 308. The open end 302 receives a corresponding end of the spring 214, which resides within the cavity 308. In the illustrated embodiment, the peripheral wall 306 is cylindrical in shape and matches a cylindrical shape of the transverse bore 222. The peripheral wall 306 defines a peripheral outer surface 310 that seals against an inner surface 311 of the transverse bore 222. Each piston 300 further includes an end wall 312 coupled to the peripheral wall 306 at the closed end 304. The end wall 312 resides between the end of the spring 214 and the blade 212.

In operation, the pistons 300 reciprocate in the radial direction within the transverse bore 222, following the reciprocating motion of the blades 212. The pistons 300 limit or prevent the flow of hydraulic fluid through the transverse bore 222. As such, the flow of the hydraulic fluid is more effectively confined to the first passageway 262 and the second passageway 264 (FIG. 9). The pistons 300 therefore contribute to better regulation of the flow of hydraulic fluid through the impulse assembly 132 and improve performance of the impulse assembly 132.

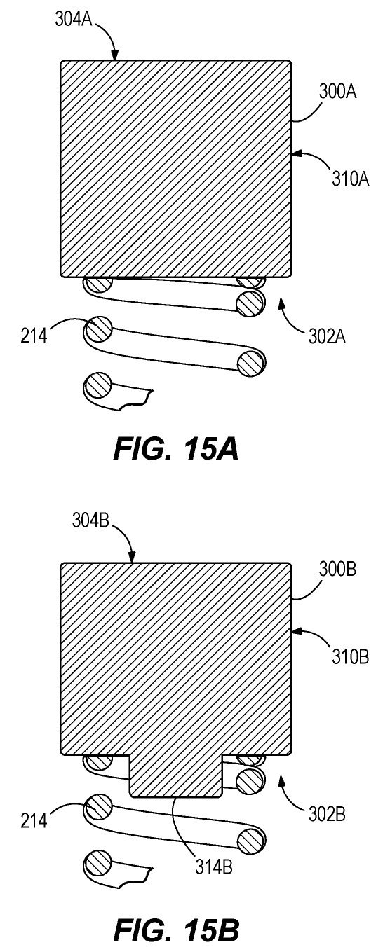

FIG. 15A illustrates a piston 300A according to another embodiment. The piston 300A differs from the piston 300 by not having an open end or defining a cavity. Instead, the piston 300A is closed at both of first and second ends 302A, 304A. The spring 214 contacts a bottom surface of the first end 302A. Like the piston 300, the piston 300A also defines a peripheral outer surface 310A which contacts the inner surface 311 of the transverse bore 222.

FIG. 15B illustrates a piston 300B according to another embodiment. The piston 300B also differs from the piston 300 by not having an open end or defining a cavity. Instead, the piston 300B is closed at both of first and second ends 302B, 304B. The spring 214 contacts a bottom surface of the first end 302B. The first end 302B also defines a protrusion 314B which is received by the end of the spring 214. The protrusion 314B can prevent the spring 214 from buckling during operation. Like the piston 300, the piston 300B also defines a peripheral outer surface 310B which contacts the inner surface 311 of the transverse bore 222.

Although the disclosure has been described in detail with reference to certain preferred embodiments, variations and modifications exist within the scope and spirit of one or more independent aspects of the disclosure as described.

What is claimed is:

1. A power tool configured to deliver torque impulses to a tool bit, the power tool comprising:
a housing;
a motor positioned within the housing; and
an impulse assembly supported within the housing and configured to be driven by the motor, the impulse assembly including an anvil assembly and a hammer assembly configured to impart a torque impulse to the anvil assembly, the impulse assembly defining a hammer chamber and an anvil chamber each containing a hydraulic fluid;
wherein the anvil assembly includes:
an anvil defining a passageway communicating between the hammer chamber and the anvil chamber,
a blade coupled to the anvil and configured to be impacted by the hammer assembly,
a biasing member configured to bias the blade toward the hammer assembly, and
a piston positioned between the biasing member and the blade.

2. The power tool of claim 1, wherein the anvil defines a transverse bore and the piston is positioned within the transverse bore.

3. The power tool of claim 2, wherein the biasing member comprises a spring positioned within the transverse bore.

4. The power tool of claim 3, wherein the piston is configured to reciprocate within the transverse bore in response to movement of the blade.

5. The power tool of claim 2, wherein the piston is configured to limit fluid flow through the transverse bore.

6. The power tool of claim 2, wherein the piston includes a peripheral outer surface configured to seal against an inner surface of the transverse bore.

7. The power tool of claim 1, wherein the piston includes an open end defining a cavity that receives a portion of the biasing member.

8. The power tool of claim 1, wherein the piston is closed at opposite ends and contacts both the biasing member and the blade.

9. The power tool of claim 1, wherein the passageway includes a restricted flow passageway having an adjustable cross-sectional area.

10. A power tool configured to deliver torque impulses to a tool bit, the power tool comprising:
a housing;
a motor positioned within the housing; and
an impulse assembly supported within the housing and configured to be driven by the motor, the impulse assembly including an anvil assembly and a hammer assembly configured to impart a torque impulse to the anvil assembly;
wherein the anvil assembly includes:
an anvil defining a transverse bore,
a blade coupled to the anvil and configured to be impacted by the hammer assembly,
a biasing member configured to bias the blade toward the hammer assembly, and
a piston positioned within the transverse bore between the biasing member and the blade.

11. The power tool of claim 10, wherein the piston includes a peripheral wall defining an open end and an end wall defining a closed end.

12. The power tool of claim 11, wherein the peripheral wall further defines a cavity that receives a portion of the biasing member.

13. The power tool of claim 10, wherein the anvil further defines an axial bore intersecting the transverse bore.

14. The power tool of claim 10, wherein the biasing member comprises a spring positioned within the transverse bore.

15. The power tool of claim 14, wherein the piston includes a protrusion configured to engage the spring and inhibit buckling of the spring.

16. The power tool of claim 10, wherein the impulse assembly further includes a camshaft configured to selectively open and close a fluid passageway between a hammer chamber and an anvil chamber.

17. The power tool of claim 16, wherein the camshaft rotates with the hammer assembly.

18. An impulse assembly for a power tool, the impulse assembly comprising:
an anvil assembly including an anvil defining a transverse bore;
a blade movably coupled to the anvil and configured to be impacted by a hammer assembly;
a biasing member positioned in the transverse bore and configured to bias the blade toward an extended position; and
a piston positioned in the transverse bore between the biasing member and the blade;
wherein the piston is configured to reciprocate within the transverse bore with movement of the blade and to restrict fluid flow through the transverse bore.

19. The impulse assembly of claim 18, wherein the piston includes a peripheral wall having an outer surface that sealingly engages an inner surface of the transverse bore to inhibit hydraulic fluid flow through the transverse bore.

20. The impulse assembly of claim 18, wherein the piston is cup‑shaped and defines an open end forming a cavity that receives an end portion of the biasing member.
